(19) United States
(12) Patent Application Publication
(10) Pub. No.: US 2006/0258144 A1
(43) Pub. Date: Nov. 16, 2006

(54) METHOD OF FORMING METAL INTERCONNECT FOR SEMICONDUCTOR DEVICE BASED ON SELECTIVE DAMASCENE PROCESS

(76) Inventors: Tae-Hoon CHOI, Daejeon (KR); Hyung Suk Lee, Daejeon (KR); Sung-Il Chang, Deajeon (KR); Jun-Bo Yoon, Daejeon (KR)

Correspondence Address: HARRY K. AHN, Esq.;REED SMITH LLP, 599 LEXINGTON AVENUE, NEW YORK, NY, 10022-7650, US

(21) Appl. No.: 11/382,175

(22) Filed: May 8, 2006

(30) Foreign Application Priority Data
May 10, 2005 (KR) 10-2005-0038722

(51) Int. Cl. H01L 21/4763

(52) U.S. Cl. 438/618

(57) ABSTRACT

Provided is a method for forming metal interconnect only in desired regions of a semiconductor device based on selective damascene using an insulation material against plating to form the metal interconnect without a Chemical Mechanical Polishing (CMP) or an additional lithography process. The selective damascene is stable and effective in the respect of cost and simplifies the semiconductor interconnect forming process.

This Nonprovisional application claims priority under 35 U.S.C. § 119(a) on Patent Application No. 10-2005-0038722 filed in Korea on May 10, 2005, the entire contents of which are hereby incorporated by reference.

### BACKGROUND OF THE INVENTION

1. Field of the Invention

The present invention relates to a method for forming metal interconnect and, more particularly, to a method for forming metal interconnect in desired regions without Chemical Mechanical Polishing (CMP) or additional lithography when interconnect is formed in a semiconductor device or a Micro Electro Mechanical Systems (MEMS) structure is fabricated.

2. Description of the Background Art

Generally, aluminum (Al) is used for metal interconnect in a semiconductor device. However, since aluminum has a large specific resistance and a low reliability, it is difficult to use it for metal interconnect in the device with the high integration and miniaturization.

Copper (Cu) is superior to aluminum in electrical characteristics and reliability but copper has a shortcoming that it is weak to dry etching. Thus, researchers have studied to develop a method that can form plugs and interconnect simultaneously without dry etching. This method is called a dual damascene process and it is revealed in a book entitled “Silicon Processing for the VLSI Era Volume-4 Deep-Submicron Process Technology,” written by Stanley Wolf pp. 583˜584.

Typical Cu dual damascene processing will be described hereinafter with reference to the accompanying drawing.

FIGS. 1A to 1D are cross-sectional views showing a conventional metal interconnect forming method using Chemical Mechanical Polishing (CMP).

Referring to FIG. 1A, a pattern comprising a via hole 103 and trenches 104 is formed on an insulation layer 102 formed on a semiconductor substrate 101 having a predetermined lower structure.

Referring to FIG. 1B, a metal seed layer 105 is deposited on the patterned insulation layer 102.

Referring to FIG. 1C, the entire surface of the deposited metal seed layer 105 is plated to thereby form a plated film 106.

Referring to FIG. 1D, plugs and metal interconnect are formed by polishing the plated film 106 in the CMP method.

Conventional CMP method, however, has a problem that it requires much material, processing, processing time and cost, because it is performed after the entire surface of a structure is plated and the plated film is removed through the polishing.

Meanwhile, Micro Electro Mechanical System (MEMS) processing, which is researched in diverse areas such as ultrahigh frequency circuits, medial diagnosis devices, and optical devices, is based on the semiconductor device processing but there is a difference between the MEMS and the CMP.

The MEMS process is used to fabricate devices having a relatively large size ranging from several to hundreds of micrometers and the MEMS process features a thick photoresist process, a thick plating process, and a process of forming a three-dimensional structure by using a sacrificial layer and then performing release.

Particularly, the MEMS process which is compatible with a Complementary Metal-Oxide Semiconductor (CMOS) process is widely used these days to form a thick structure by using a photoresist as a mold. The process of forming a multi-layer structure by using the photoresist as a mold is still under research due to its procedural difficulty.

As described in the metal interconnecting for a semiconductor device, the CMP process has a problem that the lower structure may be damaged during polishing because of the soft property of the photoresist.

To fabricate a metal structure without the CMP process, a process illustrated in FIGS. 2A to 2F has been suggested in KR Patent No. 0,449,026.

The process suggested in the KR Patent No. 0,449,026 will be described hereinafter with reference to drawings.

Referring to FIG. 2A, a semiconductor substrate 201 comprising a predetermined lower structure is coated with a photoresist and then patterned to thereby form a first photoresist mold 202 comprising a via hole 203 and trenches 204.

Referring to FIG. 2B, a metal seed layer 205 is deposited on the patterned first photoresist mold 202 for plating.

Referring to FIG. 2C, the deposited metal seed layer 205 is coated with a second photoresist 206.

Referring to FIG. 2D, the second photoresist 206 is patterned to protect the uppermost parts of the metal seed layer from being plated.

Referring to FIG. 2E, the via hole 203 and the trenches 204 of the first photoresist mold 202 are filled with metal through plating to thereby form a predetermined structure.

Referring to FIG. 2F, the second photoresist 206 and the uppermost parts of the metal seed layer 205 are etched to be removed.

The major problem of the above described process is that the cost is increased due to the additional lithography process. Also, there is a problem that the first photoresist mold 202 in the lower part may be moved during baking of the second photoresist 206 so that the metal seed layer 205 cut off.

### SUMMARY OF THE INVENTION

Accordingly, an object of the present invention is to solve at least the problems and disadvantages of the background art.

It is an object of the present invention to provide a method for forming semiconductor metal interconnect only in desired regions based on selective damascene using an insulation material against plating without a Chemical Mechanical Polishing (CMP) or an additional lithography process. The selective damascene is stable and effective in the respect of cost and it can simplify the semiconductor metal interconnect forming process.

In accordance with an aspect of the present invention, provided is a method for forming metal interconnect in via holes and trenches of an insulation layer in a semiconductor substrate based on selective damascene, comprising the steps of a) depositing a metal seed layer for plating on entire surface of a first insulation layer, b) selectively coating upper parts of the metal seed layer that are not desired to be plated with a second insulation material, c) filling the via holes and the trenches with metal by electroplating the metal seed layer, d) removing the second insulation layer, and e) removing the metal seed layer of the uppermost parts.

The first insulation layer may be formed of at least any one of the group consisting of silicon dioxide, nitride, photoresist, and organic polymer.

The second insulation layer comprises a material adhesive to the metal seed layer, the adhesive material including ink or a self assembled monolayer (SAM) material.

The insulation material to form the second insulation layer may be applied in a contact printing method using a roller or a stamp.

The second insulation layer may be removed by using at least one method of the group consisting of wet etching using a proprietary removal solution, dry etching, and soft polishing.

The semiconductor metal interconnect forming method further comprises the step f) performing Chemical Mechanical Polishing (CMP) to improve planarity after the step e).

### BRIEF DESCRIPTION OF THE DRAWINGS

The invention will be described in detail with reference to the following drawings in which like numerals refer to like elements.

FIGS. 1A to 1D are cross-sectional views showing a conventional metal interconnect forming method based on a dual damascene process using Chemical Mechanical Polishing (CMP) for a semiconductor device;

FIGS. 2A to 2F are cross-sectional views showing a conventional semiconductor metal interconnect forming process based on a selective damascene process comprising an additional lithography process; and

FIGS. 3A to 3E are cross-sectional views showing a semiconductor metal interconnect forming process based on selective damascene in accordance with an embodiment of the present invention.

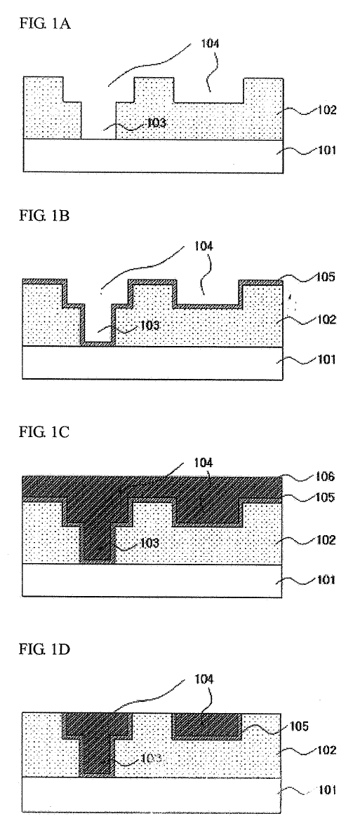

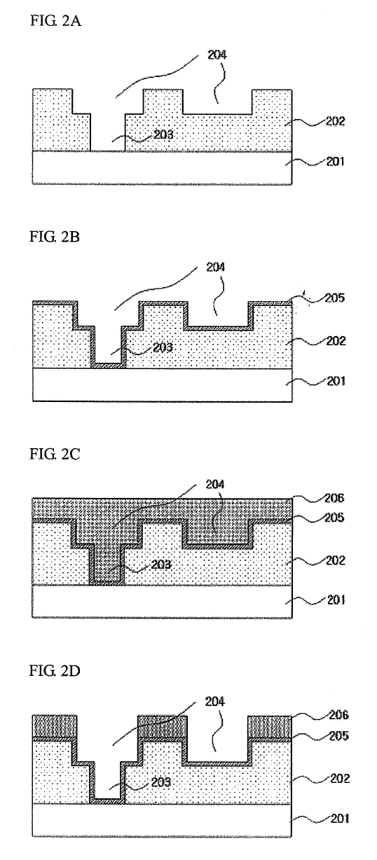

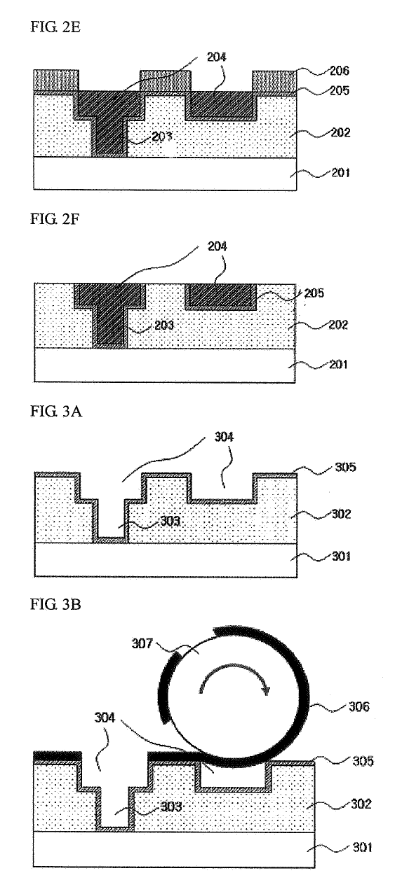

### DETAILED DESCRIPTION OF PREFERRED EMBODIMENTS

Preferred embodiments of the present invention will be described in a more detailed manner with reference to the drawings.

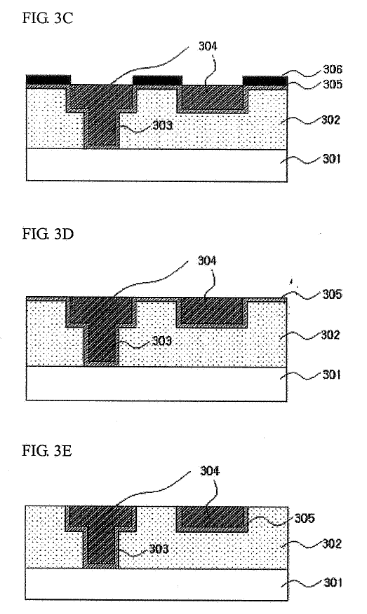

FIGS. 3A to 3E are cross-sectional views showing a semiconductor metal interconnect forming process based on selective damascene in accordance with an embodiment of the present invention. The semiconductor metal interconnect forming process based on selective damascene will be described hereinafter with reference to the drawings.

Referring to FIG. 3A, a metal seed layer 305 is deposited on a first insulation layer 302 comprising a via hole 303 and trenches 304 on a semiconductor substrate 301.

Referring to FIG. 3B, the uppermost parts of the metal seed layer 305 are coated with an anti-plating insulation material to thereby form a second insulation layer 306, because the uppermost parts of the deposited metal seed layer 305 should not be plated. Herein, the insulation material that forms the first insulation layer 302 may be any one selected from the group comprising silicon dioxide, nitride, photoresist, and organic polymer.

Also, the insulation material that forms the second insulation layer 306 comprises an adhesive material such as ink or a self assembled monolayer (SAM) material. In the present embodiment, the metal seed layer 305 is coated with the second insulation layer 306 in a contact printing method by using ink which is easily transferred and a roller 307. The contact printing using a stamp or a roller 307 is preferred as a method for forming the second insulation layer 306.

Referring to FIG. 3C, metal interconnect is formed by electroplating the metal seed layer 305, while protecting the uppermost parts of the metal seed layer 305 from the plating with the second insulation layer 306, and filling the via hole 303 and the trenches 304.

Referring to FIG. 3D, the second insulation layer 306 is removed by using a proprietary removal solution or through dry etching. The second insulation layer 306 may be removed through any one selected from the group comprising a method using the proprietary removal solution, dry etching, and soft polishing.

Subsequently, as shown in FIG. 3E, the formation of the metal interconnect in the semiconductor substrate is completed by etching the uppermost parts of the metal seed layer 305. Furthermore, CMP may be additionally performed to improve the planarity.

With the above-described semiconductor interconnect forming method suggested in the present invention, only the desired region of molds can be plated by coating the regions that are not desired to be plated with an insulation material. Therefore, it is possible to form interconnect without the cost-consuming and procedurally difficult polishing. The semiconductor interconnect forming method of the present invention is effective in the respect of cost and reduces wasteful consumption of material by performing the damascene process without the CMP. Also, when it is applied to fabrication of MEMS structures, it can also makes the fabrication process easy and stable, as it does in the semiconductor metal interconnect forming process.

The invention being thus described, it will be obvious that the same may be varied in many ways. Such variations are not to be regarded as a departure from the spirit and scope of the invention and all such modifications as would be obvious to one skilled in the art are intended to be included within the scope of the following claims.

What is claimed is:

1. A method for forming metal interconnect in via holes and trenches of an insulation layer in a semiconductor substrate, comprising:
a) depositing a metal seed layer for plating on a first insulation layer;
b) selectively coating a second insulation material on the metal seed layer;
c) filling the via holes and the trenches with metal by electroplating the metal seed layer; and
d) removing the second insulation layer and the metal seed layer below the second insulation layer.

2. The method as claimed in claim 1, wherein the first insulation layer comprises at least any one of silicon oxide, nitride, photoresist, and organic polymer.

3. The method as claimed in claim 1, wherein the second insulation layer comprises a adhesive material having ink or a self assembled monolayer (SAM) material.

4. The method as claimed in claim 1, wherein the second insulation layer is coated by a contact printing method using a roller or a stamp.

5. The method as claimed in claim 1, wherein the second insulation layer is removed by one of a method of a wet etching using a proprietary removal solution, dry etching, and soft polishing.

6. The method as claimed in claim 1, further comprising:
e) performing Chemical Mechanical Polishing (CMP) to improve planarity after the step d).
